(19) United States
(12) Patent Application Publication
(10) Pub. No.: US 2021/0357672 A1
(43) Pub. Date: Nov. 18, 2021

(54) DISPLAY SUBSTRATE, METHOD FOR MANUFACTURING THE SAME AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Kuo SUN, Beijing (CN); Yang WANG, Beijing (CN); Mingche HSIEH, Beijing (CN); Haijun YIN, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 16/346,435

(22) PCT Filed: Aug. 30, 2018
(86) PCT No.: PCT/CN2018/103145

§ 371 Date: Apr. 30, 2019

(30) Foreign Application Priority Data
Jan. 12, 2018 (CN) 201810031285.3

(51) Int. Cl. G06K 9/20; H01L 27/32; H01L 51/56; G06K 9/00; G01S 17/08; G01J 1/42

(52) U.S. Cl. CPC G06K 9/209; H01L 27/3234; H01L 27/3272; H01L 51/56; H01L 2227/323; G06K 9/00221; G01S 17/08; G01J 1/4204; G06K 9/0004

(57) ABSTRACT

A display substrate, a method for manufacturing the same and a display device are provided. The display substrate includes a base substrate and a thin film transistor array arranged on the base substrate. Multiple pixels arranged in an array are provided in an effective display region of the display substrate. The effective display region includes an optical element arrangement region and other display regions, and a transmittance of the optical element arrangement region is larger than transmittances of the other display regions. In the optical element arrangement region, an optical element is arranged on a side of the base substrate away from the thin film transistor array, and the optical element emits and receives light that is transmitted through the display substrate.

### CROSS-REFERENCE TO RELATED APPLICATION

This application claims a priority to Chinese Patent Application No. 201810031285.3 filed on Jan. 12, 2018, the disclosure of which is incorporated in its entirety by reference herein.

### TECHNICAL FIELD

The present disclosure relates to the field of display technology, in particular to a display substrate, a method for manufacturing the same and a display device.

### BACKGROUND

With the continuous improvement in industrial design and product assembling process, the utilization of internal space of a smart phone increases as the size of the smart phone increases. Nowadays, customers pursue not only large screens but also compact phone bodies while ensuring the sizes of the screens. Due to hardware homogenization, “screen-to-body ratio” has become a popular word in describing the appearance of a cellphone.

### SUMMARY

The present disclosure provides a display substrate, a method for manufacturing the same, and a display device.

In a first aspect, the present disclosure provides a display substrate, including a base substrate and a thin film transistor array arranged on the base substrate. Multiple pixels arranged in an array are provided in an effective display region of the display substrate. The effective display region includes an optical element arrangement region and other display regions, and a transmittance of the optical element arrangement region is larger than transmittances of the other display regions. In the optical element arrangement region, an optical element is arranged on a side of the base substrate away from the thin film transistor array, and the optical element emits and receives light that is transmitted through the display substrate.

Optionally, the display substrate further includes a light-shielding layer between the thin film transistor array and the base substrate. An orthographic projection of an active layer of each thin film transistor onto the base substrate falls within an orthographic projection of the light-shielding layer onto the base substrate, and the light-shielding layer includes a light-shielding pattern and an imaging pattern.

Optionally, the optical element arrangement region includes a first region. The imaging pattern corresponds to the first region and is provided with multiple imaging holes arranged in an array. The optical element includes a fingerprint recognition structure, and the fingerprint recognition structure is arranged corresponding to the first region.

Optionally, the optical element arrangement region includes a second region. The light-shielding pattern corresponds to the second region and the other display regions. The optical element includes at least one of a face recognition circuit, a distance detection circuit and an environment light detection circuit, and the at least one of the face recognition circuit, the distance detection circuit and the environment light detection circuit is arranged corresponding to the second region.

Optionally, a density of the pixels in the optical element arrangement region is smaller than densities of the pixels in the other display regions.

Optionally, the density of the pixels in the optical element arrangement region is lower than 200 PPI (Pixels Per Inch).

Optionally, no pixel is arranged in the optical element arrangement region.

Optionally, a size of each of the pixels in the optical element arrangement region is smaller than a size of each of the pixels in the other display regions.

Optionally, each thin film transistor has a top-gate structure, and an orthographic projection of an active layer of each thin film transistor onto the base substrate falls within an orthographic projection of a gate electrode of the thin film transistor onto the base substrate.

In a second aspect, a method for manufacturing a display substrate is provided in the present disclosure. The display substrate includes a base substrate and a thin film transistor array arranged on the base substrate, and multiple pixels arranged in an array are provided in an effective display region of the display substrate. The manufacturing method includes: forming the base substrate; forming the thin film transistor array on the base substrate; and forming a light-emitting layer, a cathode and an anode on the thin film transistor array. The effective display region includes an optical element arrangement region and other display regions, and a transmittance of the optical element arrangement region is larger than transmittances of the other display regions. The manufacturing method further includes: forming an optical element on a side of the base substrate away from the thin film transistor array in the optical element arrangement region, where the optical element emits and receives light that is transmitted through the display substrate.

Optionally, the manufacturing method further includes: forming a light-shielding layer between the thin film transistor array and the base substrate. An orthographic projection of an active layer of each thin film transistor onto the base substrate falls within an orthographic projection of the light-shielding layer onto the base substrate, and the light-shielding layer includes a light-shielding pattern and an imaging pattern.

Optionally, the optical element arrangement region includes a first region, the imaging pattern corresponds to the first region and is provided with multiple imaging holes arranged in an array, and the optical element includes a fingerprint recognition structure. The manufacturing method further includes: forming the fingerprint recognition structure in the first region and at the side of the base substrate away from the thin film transistor array.

Optionally, the optical element arrangement region includes a second region, the light-shielding pattern corresponds to the second region and the other display regions, and the optical element includes at least one of a face recognition circuit, a distance detection circuit and an environment light detection circuit. The manufacturing method further includes: forming the at least one of the face recognition circuit, the distance detection circuit and the environment light detection circuit in the second region at the side of the base substrate away from the thin film transistor array.

In a third aspect, the present disclosure provides a display device, including the above-described display substrate.

Optionally, the display device is a flexible display device. The display device further includes a bottom film attached on a non-display side of the display substrate, and a buffering shielding layer located on a side of the bottom film away from the display substrate. An opening is provided in the bottom film and the buffering shielding layer at a location corresponding to the optical element arrangement region, and the optical element is arranged at the opening.

### BRIEF DESCRIPTION OF THE DRAWINGS

FIG. 1 schematically shows locations of a light-shielding pattern and an active layer of a thin film transistor according to some embodiments of the present disclosure;

FIG. 2 is a schematic diagram of an imaging pattern according to some embodiments of the present disclosure;

FIG. 3 is a schematic plan view of a display device according to some embodiments of the present disclosure; and

FIG. 4 and FIG. 5 each is a schematic sectional view of a display device according to some embodiments of the present disclosure.

### DETAILED DESCRIPTION

To better clarify technical problems to be solved, technical solutions and advantages according to some embodiments of the preset disclosure, detailed description is given based on drawings in conjunction with embodiments.

A narrow-bezel cellphone may improve a screen-to-body ratio and may be equipped with a large display screen within a small cellphone body, thereby leading to more perfect video and game experiences, and improving portability of the cellphone. Furthermore, the narrow-bezel cellphone has excellent visual effects, a fixed-size cellphone body may accommodate a larger screen, or a fixed-size screen may be accommodated in a more compact cellphone body.

Nowadays, a bezel of a cellphone product needs to provide some space for arranging structures such as a front-facing camera, a range sensor, an environment light sensor and a fingerprint recognition sensor. Consequently, the cellphone product cannot achieve real sense of full screen display.

In some embodiments, the present disclosure provides a display substrate, a method for manufacturing the same, and a display device, to increase a scree-to-body ratio of the display device and optimizing a display effect of the display device.

A display substrate is provided in some embodiments of the present disclosure. The display substrate may include a base substrate and a thin film transistor array arranged on the base substrate. Multiple pixels arranged in an array are provided in an effective display region of the display substrate. The effective display region includes an optical element arrangement region and other display regions. A transmittance of the optical element arrangement region is larger than transmittances of the other display regions. In the optical element arrangement region, an optical element is arranged on a side of the base substrate away from the thin film transistor array. The optical element emits light and such light transmits through the display substrate, and the optical element receives light that is transmitted through the display substrate.

In some embodiments of the present disclosure, the transmittance of the optical element arrangement region of the display substrate is larger than the transmittances of the other display regions; the optical element is arranged at a non-display side of the display substrate so there is no need to arrange the optical element at a bezel of the display device; and since the transmittance of the optical element arrangement region is relatively large, lights emitted from and received by the optical element may transmit through the display substrate. In view of the above, there is no need to reserve a space at the bezel of the display device to arrange the optical element, the screen-to-body ratio of the display device is enhanced, and the display effect of the display device is optimized.

Furthermore, the display substrate may further include a light-shielding layer between the thin film transistor array and the base substrate. An orthographic projection of an active layer of each thin film transistor onto the base substrate falls within an orthographic projection of the light-shielding layer onto the base substrate. The light-shielding layer includes a light-shielding pattern and an imaging pattern.

For example, in a case that the thin film transistor is a low-temperature polysilicon thin film transistor, and the active layer of the thin film transistor is made of a low-temperature polysilicon, the light-shielding layer may shield light emitted by a light source in the optical element, such that the light is prevented from striking onto the active layer made of the low-temperature polysilicon, and the performance of the low-temperature polysilicon thin film transistor may not be affected. The light-shielding layer may be made of a metal such as Mo, or may be made of other light-shielding materials, which is not limited herein.

In some embodiments of the present disclosure, the optical element arrangement region may include a first region. The imaging pattern corresponds to the first region and is provided with multiple imaging holes arranged in an array. The optical element may include a fingerprint recognition structure. The fingerprint recognition structure may be arranged corresponding to the first region, for example, the fingerprint recognition structure is arranged directly facing the first region. A light source in the fingerprint recognition structure emits light out of the display substrate, and the light is reflected after arriving at a finger of a user. A photoelectric converter is arranged in the fingerprint recognition structure. Via the first region having a relatively high transmittance, the reflected light is received by the photoelectric converter based on a pin-hole imaging principle, and a fingerprint of the user may be imaged on the photoelectric converter through the imaging holes, thereby accomplishing fingerprint acquisition at corresponding imaging holes. The photoelectric converter may utilize photosensitive components such as Complementary Metal Oxide Semiconductor (CMOS) or Charge-coupled Device (CCD), to acquire the fingerprint.

In some embodiments of the present disclosure, the optical element arrangement region may further include a second region. The light-shielding pattern corresponds to the second region and the other display regions. The optical element includes at least one of a face recognition circuit, a distance detection circuit and an environment light detection circuit. The at least one of the face recognition circuit, the distance detection circuit and the environment light detection circuit is arranged corresponding to the second region. The at least one of the face recognition circuit, the distance detection circuit and the environment light detection circuit may emit light or receive light that is transmitted through the second region of the display substrate, to perform an optical detection.

The transmittance of the optical element arrangement region may be enhanced with many approaches. For example, a pixel density of the optical element arrangement region may be set to be smaller than pixel densities of the other display regions. With the optical element arrangement region having a low pixel density, a light-shielding effect of pixels may be alleviated, such that the optical element may receive sufficient external light that is transmitted through the display substrate corresponding to the optical element arrangement region.

The pixel densities of the other display regions of the display substrate are usually higher than 500 PPI. In an optional embodiment, the pixel density of the optical element arrangement region is lower than 200 PPI (Pixels Per Inch), such that the transmittance of the optical element arrangement region is high enough, and the optical element can receive sufficient external light that is transmitted through the display substrate corresponding to the optical element arrangement region. In addition, since the optical element arrangement region is stilled provided with pixels, the optical element arrangement region can still display, and image integrity is not affected. For example, the optical element arrangement region may display images of not high display requirements, such as images of battery level, signal strength, time and virtual buttons.

In some other embodiments of the present disclosure, the optical element arrangement region may be constructed into a region having no pixels. The optical element arrangement region maintains in a transparent state and no image is displayed there, such that the optical element can receive sufficient external light via the display substrate corresponding to the optical element arrangement region.

Furthermore, sizes of pixels corresponding to the optical element arrangement region may be set to be smaller than sizes of pixels in the other display regions. Hence, the light-shielding effect of the pixels can be further alleviated, and the optical element can receive sufficient external light via the display substrate corresponding to the optical element arrangement region.

Furthermore, the optical element arrangement region may be arranged at a certain corner of the effective display region, for example, an upper right corner, an upper left corner or a lower right corner, to best alleviate an effect on a displayed image.

Optionally, the thin film transistor may have a top-gate structure, an orthographic projection of an active layer of the thin film transistor onto the base substrate falls within an orthographic projection of a gate electrode of the thin film transistor onto the base substrate, such that the gate electrode of the thin film transistor can shield the external light, external light is prevented from striking onto the active layer of the thin film transistor and accordingly, the performance of the thin film transistor is not affected.

A method for manufacturing a display substrate is further provided according to some embodiments of the present disclosure. The display substrate includes a base substrate and a thin film transistor array arranged on the base substrate. Multiple pixels arranged in an array are provided in an effective display region of the display substrate.

The manufacturing method includes: forming the base substrate; forming the thin film transistor array on the base substrate; and forming a light-emitting layer, a cathode and an anode on the thin film transistor array. The effective display region includes an optical element arrangement region and other display regions. A transmittance of the optical element arrangement region is larger than transmittances of the other display regions.

The manufacturing method further includes: forming an optical element on a side of the base substrate away from the thin film transistor array and in the optical element arrangement region, where the optical element emits light and receives light via the display substrate.

In some embodiments of the present disclosure, the transmittance of the optical element arrangement region of the display substrate is larger than the transmittances of the other display regions; the optical element is arranged at a non-display side of the display substrate so there is no need to arrange the optical element at a bezel of the display device; and since the transmittance of the optical element arrangement region is relatively large, lights emitted from and received by the optical element can transmit through the display substrate. In view of the above, there is no need to reserve a space at the bezel of the display device to arrange the optical element, the screen-to-body ratio of the display device is enhanced, and the display effect of the display device is optimized.

Furthermore, the manufacturing method may include: forming a light-shielding layer between the thin film transistor array and the base substrate. An orthographic projection of an active layer of each thin film transistor onto the base substrate falls within an orthographic projection of the light-shielding layer onto the base substrate. The light-shielding layer includes a light-shielding pattern and an imaging pattern.

For example, in a case that the thin film transistor is a low-temperature polysilicon thin film transistor, and the active layer of the thin film transistor is made of a low-temperature polysilicon, the light-shielding layer may shield light emitted by a light source in the optical element, such that the light is prevented from striking onto the active layer made of the low-temperature polysilicon, and the performance of the low-temperature polysilicon thin film transistor may not be affected. The light-shielding layer may be made of a metal such as Mo, or may be made of other light-shielding materials, which is not limited herein.

In some embodiments of the present disclosure, the optical element arrangement region may include a first region. The imaging pattern corresponds to the first region and is provided with multiple imaging holes arranged in an array. The optical element may include a fingerprint recognition structure. The fingerprint recognition structure may be arranged corresponding to the first region, for example, the fingerprint recognition structure is arranged directly facing the first region. A light source in the fingerprint recognition structure emits light out of the display substrate and the light is reflected after arriving at a finger of a user. A photoelectric converter is arranged in the fingerprint recognition structure. Via the first region having a relatively high transmittance, the reflected light is received by the photoelectric converter based on a pin-hole imaging principle, and a fingerprint of the user may be imaged on the photoelectric converter through the imaging holes, thereby accomplishing fingerprint acquisition at corresponding imaging holes. The photoelectric converter may utilize light sensing components such as Complementary Metal Oxide Semiconductor (CMOS) or Charge-coupled Device (CCD), to acquire the fingerprint.

In some embodiments of the present disclosure, the optical element arrangement region may further include a second region. The light-shielding pattern corresponds to the second region and the other display regions. The optical element includes at least one of a face recognition circuit, a distance detection circuit and an environment light detection circuit. The at least one of the face recognition circuit, the distance detection circuit and the environment light detection circuit is arranged corresponding to the second region. The at least one of the face recognition circuit, the distance detection circuit and the environment light detection circuit may emit light or receive light via the second region of the display substrate, to perform an optical detection.

In some embodiments of the present disclosure, the method for manufacturing the display substrate may include following steps 1 to 9.

Step 1 includes: providing a base substrate and forming a light-shielding layer on the base substrate.

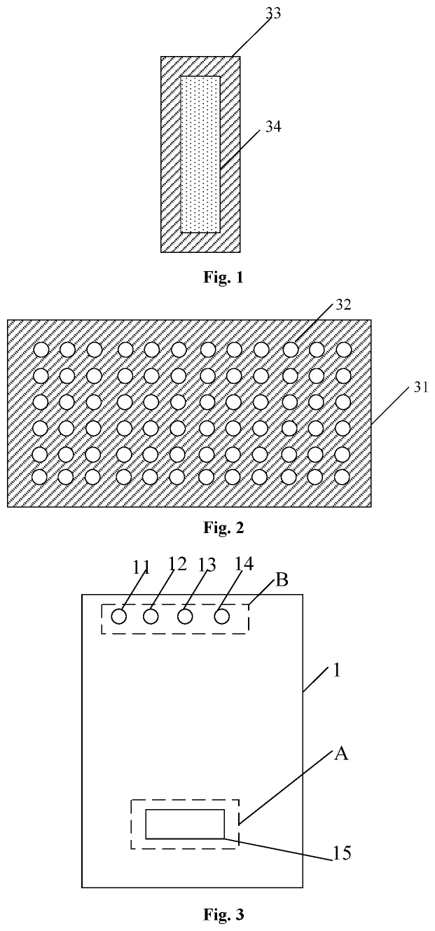

The base substrate may be a glass substrate or a quartz substrate. For example, a light-shielding layer having a thickness of about 300 to 1500 Å is deposited on the base substrate in a sputtering or thermal evaporation manner. The light-shielding layer may be made of Mo. A layer of photoresist is coated on the light-shielding layer and is exposed using a mask to generate a photoresist unreserved region and a photoresist reserved region. The photoresist reserved region corresponds to a region where a pattern of the light-shielding layer is located. The photoresist unreserved region corresponds to a region except for the region where the pattern of the light-shielding layer is located. A developing process is performed, the photoresist in the photoresist unreserved region is completely removed, and a thickness of the photoresist in the photoresist reserved region is maintained unchanged. The light-shielding layer in the photoresist unreserved region is completely etched via an etching process, and the remained photoresist is peeled off to form the pattern of the light-shielding layer. The pattern of the light-shielding layer includes a light-shielding pattern and an imaging pattern. FIG. 1 schematically shows locations of the light-shielding pattern and the active layer of the thin film transistor according to some embodiments of the present disclosure. As shown in FIG. 1, the light-shielding pattern 33 is arranged corresponding to the active layer 34 of the thin film transistor. An orthographic projection of the active layer 34 of the thin film transistor onto the base substrate falls within an orthographic projection of the light-shielding pattern 33 onto the base substrate. The imaging pattern is arranged corresponding to a fingerprint recognition structure. As shown in FIG. 2, the imaging pattern 31 is provided with multiple imaging holes 32 arranged in an array.

Step 2 includes: forming an insulating layer and a pattern of the active layer of each thin film transistor on the base substrate after step 1.

For example, an insulating layer material and a low-temperature polysilicon material are successively deposited on the base substrate after step 1. A layer of photoresist is coated on the low-temperature polysilicon material. The photoresist is exposed using a mask to generate a photoresist unreserved region and a photoresist reserved region. The photoresist reserved region corresponds to a region where a pattern of the active layer is located. The photoresist unreserved region corresponds to a region in addition to the region where the pattern of the active layer is located. A developing process is performed, the photoresist in the photoresist unreserved region is completely removed, and a thickness of the photoresist in the photoresist reserved region is maintained unchanged. The low-temperature polysilicon material in the photoresist unreserved region is completely etched via an etching process, and remained photoresist is peeled off to form the pattern of the active layer. As shown in FIG. 1, the orthographic projection of the active layer 34 of the thin film transistor onto the base substrate falls within the orthographic projection of the light-shielding pattern 33 onto the base substrate.

Step 3 includes: forming a pattern of a gate insulating layer on the base substrate after step 2.

For example, a gate insulating layer having a thickness ranging from 500 Å to 5000 Å is deposited on the base substrate after step 2 with a manner of plasma enhanced chemical vapor deposition (PECVD). The gate insulating layer may be made of an oxide, a nitride or a nitric oxide, and a corresponding reactant gas may be SiH4, NH3, N2 or SiH2Cl2, NH3, N2. The pattern of the gate insulating layer includes a via-hole, and the light-shielding pattern 33 is electrically connected to a preset electric potential point through the via-hole penetrating through the gate insulating layer.

Step 4 includes: forming a pattern of a gate metallic layer on the base substrate after step 3.

For example, a gate metallic layer having a thickness of about 500 to 4000 Å is deposited on the base substrate after step 3 with a manner of sputtering or thermal evaporation. The gate metallic layer may be made of Cu, Al, Ag, Mo, Cr, Nd, Ni, Mn, Ti, Ta or W, or any alloy of the above metals. The gate metallic layer may have a single layer structure or a multilayer structure such as Cu\Mo, Ti\Cu\Ti, Mo\Al\Mo. A layer of photoresist is coated on the gate metallic layer, and is exposed using a mask to generate a photoresist unreserved region and a photoresist reserved region. The photoresist reserved region corresponds to a region where a pattern of the gate metallic layer is located. The pattern of the gate metallic layer includes a gate line and a gate electrode. The photoresist unreserved region corresponds to a region in addition to the region where the pattern of the gate metallic layer is located. A developing process is performed, the photoresist in the photoresist unreserved region is completely removed and a thickness of the photoresist in the photoresist reserved region is maintained unchanged. A gate metallic film in the photoresist unreserved region is completely etched via an etching process and remained photoresist is peeled off to form the pattern of the gate metallic layer.

Step 5 includes: forming an intermediate insulating layer on the base substrate after step 4.

For example, the intermediate insulating layer having a thickness of 500 to 5000 Å is deposited on the base substrate after step 4 in a PECVD manner. The intermediate insulating layer may be made of an oxide, a nitride or a nitric oxide, and a corresponding reactant gas may be SiH4, NH3, N2 or SiH2Cl2, NH3, N2.

Step 6 includes: forming a pattern of a source and drain metallic layer on the base substrate after step 5.

For example, a source and drain metallic layer having a thickness of about 2000 to 4000 Å is deposited on the base substrate after step 5 in a sputtering or thermal evaporation manner, or in other film forming manners. The source and drain metallic layer may be made of Cu, Al, Ag, Mo, Cr, Nd, Ni, Mn, Ti, Ta or W, or any alloy of the above metals. The source and drain metallic layer may have a single layer structure or a multilayer structure such as Cu\Mo, Ti\Cu\Ti, Mo\Al\Mo. A layer of photoresist is coated on the source and drain metallic layer and is exposed using a mask to generate a photoresist unreserved region and a photoresist reserved region. The photoresist reserved region corresponds to a region where a pattern of the source and drain metallic layer is located. The photoresist unreserved region corresponds to a region in addition to the region where the pattern of the source and drain metallic layer is located. A developing process is performed, the photoresist in the photoresist unreserved region is completely removed and a thickness of the photoresist in the photoresist reserved region is maintained unchanged. The source and drain metallic layer in the photoresist unreserved region is completely etched via an etching process and remained photoresist is peeled off to form the pattern of the source and drain metallic layer. The pattern of the source and drain metallic layer may include a source electrode, a drain electrode and a data line. The source electrode and the drain electrode may be connected to the active layer through via-holes penetrating through the intermediate insulating layer and the gate insulating layer.

Step 7 includes: forming a planarization layer and a pattern of a pixel definition layer on the base substrate after step 6.

For example, a layer of an organic resin may be coated on the base substrate after step 6 to form the planarization layer, and the pixel definition layer material may be deposited on the planarization layer. A layer of photoresist is coated on the pixel definition layer material and is exposed using a mask to generate a photoresist unreserved region and a photoresist reserved region. The photoresist reserved region corresponds to a region where a pattern of the pixel definition layer material is located. The photoresist unreserved region corresponds to a region in addition to the region where the pattern of the pixel definition layer material is located. A developing process is performed, the photoresist in the photoresist unreserved region is completely removed and a thickness of the photoresist in the photoresist reserved region is maintained unchanged. The pixel definition layer material in the photoresist unreserved region is completely etched via an etching process, and remained photoresist is peeled off to form a pattern of the pixel definition layer. The pixel definition layer defines multiple pixel regions.

Step 8 includes: forming an anode on the base substrate after step 7.

For example, a transparent conductive layer having a thickness of about 300 to 1500 Å is deposited on the base substrate after step 7 in a sputtering or thermal evaporation manner. The transparent conductive layer may be made of ITO, IZO or other transparent metallic oxides. A layer of photoresist is coated on the transparent conductive layer and is exposed using a mask to generate a photoresist unreserved region and a photoresist reserved region. The photoresist reserved region corresponds to a region where a pattern of an anode is located. The photoresist unreserved region corresponds to a region in addition to the region where the pattern of the anode is located. A developing process is performed, the photoresist in the photoresist unreserved region is completely removed, and a thickness of the photoresist in the photoresist reserved region is maintained unchanged. The transparent conductive layer in the photoresist unreserved region is completely etched via an etching process, and remained photoresist is peeled off to form the pattern of the anode.

Step 9 includes: forming a light-emitting layer and a cathode on the base substrate after step 8.

For example, the light-emitting layer and the cathode are formed on the base substrate after step 8 in an evaporation manner.

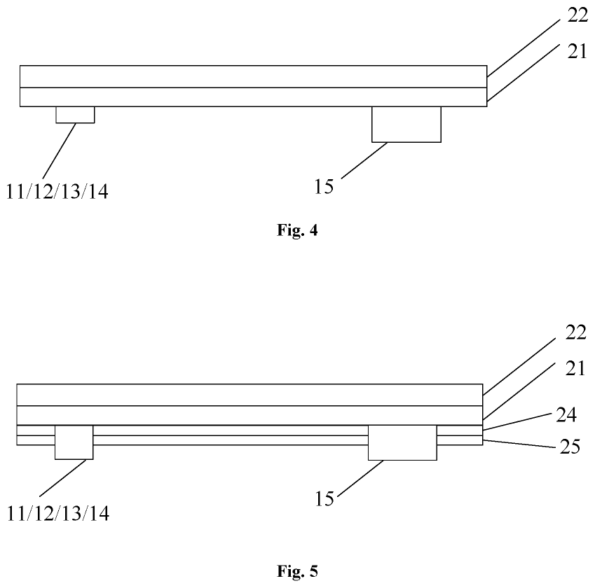

The display substrate can be made through the above steps 1 to 9. FIG. 3 is a schematic plan of a display device according to some embodiments of the present disclosure. As shown in FIG. 3, an effective display region 1 of the display device includes a first region A and a second region B. The first region A corresponds to a fingerprint recognition structure 15, and the second region B corresponds to a distance detection circuit 11, an environment light detection circuit 12, a face recognition circuit 13 and a camera 14 and so on. FIG. 4 is a schematic sectional view of the display device according to some embodiments of the present disclosure. As shown in FIG. 4, after a display substrate 21 and an encapsulation cover plate 22 are aligned and assembled, the fingerprint recognition structure 15 may be attached on a side of the display substrate 21 away from the encapsulation cover plate 22, and the fingerprint recognition structure 15 may be arranged directly facing the first region A; optical elements such as the distance detection circuit 11, the environment light detection circuit 12, the face recognition circuit 13 and the camera 14 may be attached on the side of the display substrate 21 away from the encapsulation cover plate 22, and may be arranged directly facing the second region B.

The first region A is provided with an imaging pattern 31. FIG. 2 is a schematic diagram of an imaging pattern according to some embodiments of the present disclosure. As shown in FIG. 2, the imaging pattern 31 includes multiple imaging holes 32. When a user touches the display substrate with a finger, a fingerprint may be imaged on a photoelectric converter in the fingerprint recognition structure 15 based on a pin-hole imaging principle.

A pixel density of an optical element arrangement region is set to be smaller than pixel densities of other display regions, such that a transmittance of the optical element arrangement region is higher than transmittances of the other display regions. The optical elements such as the face recognition circuit, the distance detection circuit and the environment light detection circuit may be arranged directly facing the second region. The optical elements may emit light and receive external light via the display substrate corresponding to the second region, to perform optical detections.

The distance detection circuit 11 may include an infrared emitting sensor and an infrared receiving sensor. The infrared emitting sensor emits infrared light via the display substrate corresponding to the second region B. The infrared light is reflected, after arriving at an obstacle, back to the infrared receiving sensor. The infrared receiving sensor may detect a distance based on the received infrared light.

The environment light detection circuit 12 may include a visible light detecting sensor. The environment light detection circuit 12 may accomplish an environment light detection based on a received visible light via the display substrate corresponding to the second region B.

The face recognition circuit 13 may include an infrared emitting sensor array and an infrared receiving sensor array. For example, the face recognition circuit 13 may include three thousand infrared emitting sensors arranged in an array and three thousand infrared receiving sensors arranged in an array. The infrared emitting sensors emit infrared lights via the display substrate corresponding to the second region B. The infrared lights are reflected, after arriving at an obstacle, back to the infrared receiving sensors. The infrared receiving sensors may accomplish recognition of a face of the user based on the received infrared lights.

In a case that a transmittance of the second region B is high enough, e.g., higher than 60%, the camera 14 may receive an external light via the second region B to accomplish photographing.

Since the infrared emitting sensor is arranged on the side of the display substrate 21 away from the encapsulation cover plate 22, in order to prevent a light emitted by the infrared emitting sensor from striking on the active layer of the thin film transistor and not affect the performance of the thin film transistor, it is necessary to arrange a light-shielding pattern to shield the active layer of the thin film transistor.

A display device is further provided according to some embodiments of the present disclosure. The display device includes the above-described display substrate.

The display device may be a television, a display, a digital camera, a cellphone, a tablet computer or any product or component having a displaying function. The display device may further include a flexible circuit board, a printed circuit board and a backboard.

In some embodiments of the present disclosure, the transmittance of the optical element arrangement region of the display substrate is larger than the transmittances of the other display regions; the optical element is arranged at a non-display side of the display substrate so there is no need to arrange the optical element at a bezel of the display device; and since the transmittance of the optical element arrangement region is relatively large, lights emitted from and received by the optical element can transmit through the display substrate. In view of the above, no reserved space at the bezel of the display device is necessary for arranging the optical element, the screen-to-body ratio of the display device is enhanced, and the display effect of the display device is optimized.

Furthermore, the display substrate may include a light-shielding layer between the thin film transistor array and the base substrate. An orthographic projection of an active layer of each thin film transistor onto the base substrate falls within an orthographic projection of the light-shielding layer onto the base substrate. The light-shielding layer includes a light-shielding pattern and an imaging pattern.

For example, in a case that the thin film transistor is a low-temperature polysilicon thin film transistor and the active layer of the thin film transistor is made of a low-temperature polysilicon, the light-shielding layer may shield light emitted by a light source in the optical element, such that the light is prevented from striking onto the active layer made of the low-temperature polysilicon and the performance of the low-temperature polysilicon thin film transistor may not be affected. The light-shielding layer may be made of a metal such as Mo, or may be made of other light-shielding materials, which is not limited herein.

In some embodiments of the present disclosure, the optical element arrangement region may include a first region. The imaging pattern corresponds to the first region and is provided with multiple imaging holes arranged in an array. The optical element may include a fingerprint recognition structure. The fingerprint recognition structure may be arranged corresponding to the first region, for example, the fingerprint recognition structure is arranged directly facing the first region. A light source in the fingerprint recognition structure emits light out of the display substrate, and the light is reflected after arriving at a finger of a user. A photoelectric converter is arranged in the fingerprint recognition structure. Via the first region having a relatively high transmittance, the reflected light is received by the photoelectric converter based on a pin-hole imaging principle, a fingerprint of the user may be imaged on the photoelectric converter through the imaging holes, thereby accomplishing fingerprint acquisition at corresponding imaging holes. The photoelectric converter may utilize photosensitive components such as Complementary Metal Oxide Semiconductor (CMOS) or Charge-coupled Device (CCD), to acquire the fingerprint.

In some embodiments of the present disclosure, the optical element arrangement region may further include a second region. The light-shielding pattern corresponds to the second region and the other display regions. The optical element includes at least one of a face recognition circuit, a distance detection circuit and an environment light detection circuit. The at least one of the face recognition circuit, the distance detection circuit and the environment light detection circuit is arranged corresponding to the second region. The at least one of the face recognition circuit, the distance detection circuit and the environment light detection circuit may emit light or receive light via the second region of the display substrate, to perform an optical detection.

In a case that the display device is a flexible display device, the display device may further include a bottom film attached on the non-display side of the display substrate, and a buffering shielding layer located on a side of the bottom film away from the display substrate. An opening is provided in the bottom film, and the buffering shielding layer at a location corresponding to the optical element arrangement region and the optical element is arranged at the opening, such that the bottom film and the buffering shielding layer may not shield the external light, and the optical element is ensured to receive the external light.

As shown in FIG. 3, an effective display region 1 of the display device includes a first region A and a second region B. The first region A corresponds to a fingerprint recognition structure 15, and the second region B corresponds to a distance detection circuit 11, an environment light detection circuit 12, a face recognition circuit 13 and a camera 14 and so on. FIG. 4 is a schematic sectional view of the display device according to some embodiments of the present disclosure. As shown in FIG. 4, after a display substrate 21 and an encapsulation cover plate 22 are aligned and assembled, the fingerprint recognition structure 15 may be attached on a side of the display substrate 21 away from the encapsulation cover plate 22, and the fingerprint recognition structure 15 may be arranged directly facing the first region A; optical elements such as the distance detection circuit 11, the environment light detection circuit 12, the face recognition circuit 13 and the camera 14 may be attached on the side of the display substrate 21 away from the encapsulation cover plate 22 and may be arranged directly facing the second region B. Openings are provided in a bottom film 24 and a buffering shielding layer 2S at locations corresponding to the first region A and the second region B.

The first region A is provided with an imaging pattern 31. FIG. 2 is a schematic diagram of an imaging pattern according to some embodiments of the present disclosure. As shown in FIG. 2, the imaging pattern 31 includes multiple imaging holes 32. When a user touches the display substrate with a finger, a fingerprint may be imaged on a photoelectric converter in the fingerprint recognition structure 15 based on a pin-hole imaging principle.

A pixel density of the optical element arrangement region is set to be smaller than pixel densities of other display regions of the effective display region, such that a transmittance of the optical element arrangement region is higher than transmittances of the other display regions. The optical elements such as the face recognition circuit, the distance detection circuit and the environment light detection circuit may be arranged directly facing the second region. The optical elements can emit light and receive external light via the display substrate corresponding to the second region, to perform optical detections.

The distance detection circuit 11 may include an infrared emitting sensor and an infrared receiving sensor. The infrared emitting sensor emits an infrared light via the display substrate corresponding to the second region B. The infrared light is reflected, after arriving at an obstacle, back to the infrared receiving sensor. The infrared receiving sensor may detect a distance based on the received infrared light.

The environment light detection circuit 12 may include a visible light detecting sensor. The environment light detection circuit 12 may accomplish an environment light detection based on a received visible light via the display substrate corresponding to the second region B.

The face recognition circuit 13 may include an infrared emitting sensor array and an infrared receiving sensor array. For example, the face recognition circuit 13 may include 3000 infrared emitting sensors arranged in an array and 3000 infrared receiving sensors arranged in an array. The infrared emitting sensors emit infrared lights via the display substrate corresponding to the second region B. The infrared lights are reflected, after arriving at an obstacle, back to the infrared receiving sensors. The infrared receiving sensors may accomplish recognition of a face of the user based on the received infrared lights.

In a case that a transmittance of the second region B is high enough, e.g., higher than 60%, the camera 14 may receive an external light via the second region B to accomplish photographing.

Since the infrared emitting sensor is arranged on the side of the display substrate 21 away from the encapsulation cover plate 22, in order to prevent a light emitted by the infrared emitting sensor from striking on the active layer of the thin film transistor and not affect the performance of the thin film transistor, it is necessary to arrange a light-shielding pattern to shield the active layer of the thin film transistor. As shown in FIG. 1, an orthographic projection of the active layer 34 onto the base substrate may completely fall within an orthographic projection of the light-shielding pattern 33 onto the base substrate.

In some embodiments of the present disclosure, by setting transmittances of the light-shielding layer and the display device and by arranging the optical element at the non-display side of the display substrate, no reserved space at the bezel of the display device is necessary for arranging the optical element, the screen-to-body ratio of the display device is enhanced, and the display effect of the display device is optimized.

In the embodiments of the present disclosure, numbering of the steps does not necessarily define a sequence of the steps. Variation of the sequence of the steps also falls into the protection scope of the present disclosure for one of ordinary skills in the art on the premise of paying not creative work.

Unless otherwise defined, technical terms or scientific terms used in the present disclosure should be interpreted according to common meanings thereof as commonly understood by those of ordinary skills in the art. Such terms as “first”, “second” and the like used in the present disclosure do not represent any order, quantity or importance, but are merely used to distinguish different components. Such terms as “including”, or “comprising” and the like mean that an element or an article preceding the term contains elements or items and equivalents thereof behind the term, but does not exclude other elements or items. Such terms as “connected”, or “interconnected” and the like are not limited to physical or mechanical connections, but may include electrical connections, whether direct connection or indirect connection. Such terms as “on”, “under”, “left”, “right” and the like are only used to represent a relative position relationship, and when an absolute position of a described object is changed, the relative position relationship thereof may also be changed accordingly.

It may be understood that when an element such as a layer, a film, a region or a substrate is referred to as being “on” or “under” another element, the element may be “directly” “on” or “under” the another element, or there may exist an intervening element.

The above embodiments are merely optional embodiments of the present disclosure. It should be noted that numerous improvements and modifications may be made by those skilled in the art without departing from the principle of the present disclosure, and these improvements and modifications shall also fall within the scope of the present disclosure.

1. A display substrate, comprising a base substrate and a thin film transistor array arranged on the base substrate, wherein a plurality of pixels arranged in an array is provided in an effective display region of the display substrate;
wherein the effective display region comprises an optical element arrangement region and other display regions, and a transmittance of the optical element arrangement region is larger than transmittances of the other display regions; and
wherein in the optical element arrangement region, an optical element is arranged on a side of the base substrate away from the thin film transistor array, and the optical element emits and receives light that is transmitted through the display substrate.

2. The display substrate according to claim 1, further comprising a light-shielding layer between the thin film transistor array and the base substrate, wherein an orthographic projection of an active layer of each thin film transistor onto the base substrate falls within an orthographic projection of the light-shielding layer onto the base substrate, and the light-shielding layer comprises a light-shielding pattern and an imaging pattern.

3. The display substrate according to claim 2, wherein the optical element arrangement region comprises a first region, the imaging pattern corresponds to the first region and is provided with a plurality of imaging holes arranged in an array, the optical element comprises a fingerprint recognition structure, and the fingerprint recognition structure is arranged corresponding to the first region.

4. The display substrate according to claim 2, wherein the optical element arrangement region comprises a second region, the orthographic projection of the light-shielding pattern onto the base substrate is non-overlapped with an orthographic projection of the second region onto the base substrate, the optical element comprises at least one of a face recognition circuit, a distance detection circuit and an environment light detection circuit, and the at least one of the face recognition circuit, the distance detection circuit and the environment light detection circuit is arranged corresponding to the second region.

5. The display substrate according to claim 1, wherein a density of the pixels in the optical element arrangement region is smaller than densities of the pixels in the other display regions.

6. The display substrate according to claim 5, wherein the density of the pixels in the optical element arrangement region is lower than 200 PPI (Pixels Per Inch).

7. The display substrate according to claim 5, wherein no pixel is arranged in the optical element arrangement region.

8. The display substrate according to claim 5, wherein a size of each of the pixels in the optical element arrangement region is smaller than a size of each of the pixels in the other display regions.

9. The display substrate according to claim 1, wherein each thin film transistor has a top-gate structure, and an orthographic projection of an active layer of each thin film transistor onto the base substrate falls within an orthographic projection of a gate electrode of the thin film transistor onto the base substrate.

10. A method for manufacturing a display substrate, wherein the display substrate comprises a base substrate and a thin film transistor array arranged on the base substrate, and a plurality of pixels arranged in an array is provided in an effective display region of the display substrate:
wherein the method comprises:
forming the base substrate;
forming the thin film transistor array on the base substrate; and
forming a light-emitting layer, a cathode and an anode on the thin film transistor array;
wherein the effective display region comprises an optical element arrangement region and other display regions, and a transmittance of the optical element arrangement region is larger than transmittances of the other display regions; and
wherein the method further comprises: forming an optical element on a side of the base substrate away from the thin film transistor array and in the optical element arrangement region, wherein the optical element emits and receives light that is transmitted through the display substrate.

11. The method according to claim 10, further comprising:
forming a light-shielding layer between the thin film transistor array and the base substrate, wherein an orthographic projection of an active layer of each thin film transistor onto the base substrate falls within an orthographic projection of the light-shielding layer onto the base substrate, and the light-shielding layer comprises a light-shielding pattern and an imaging pattern.

12. The method according to claim 11, wherein the optical element arrangement region comprises a first region, the imaging pattern corresponds to the first region and is provided with a plurality of imaging holes arranged in an array, and the optical element comprises a fingerprint recognition structure; and
wherein the method further comprises: forming the fingerprint recognition structure in the first region and at the side of the base substrate away from the thin film transistor array.

13. The method according to claim 11, wherein the optical element arrangement region comprises a second region, the light-shielding pattern corresponds to the second region and the other display regions, and the optical element comprises at least one of a face recognition circuit, a distance detection circuit and an environment light detection circuit; and
wherein the method further comprises: forming the at least one of the face recognition circuit, the distance detection circuit and the environment light detection circuit in the second region and at the side of the base substrate away from the thin film transistor array.

14. A display device, comprising a display substrate, wherein the display substrate comprises a base substrate and a thin film transistor array arranged on the base substrate, a plurality of pixels arranged in an array is provided in an effective display region of the display substrate;
wherein the effective display region comprises an optical element arrangement region and other display regions, and a transmittance of the optical element arrangement region is larger than transmittances of the other display regions; and
wherein in the optical element arrangement region, an optical element is arranged on a side of the base substrate away from the thin film transistor array, and the optical element emits and receives light that is transmitted through the display substrate.

15. The display device according to claim 14, wherein the display device is a flexible display device, the display device further comprises a bottom film attached onto a non-display side of the display substrate, and a buffering shielding layer located on a side of the bottom film away from the display substrate, an opening is provided in the bottom film and the buffering shielding layer at a location corresponding to the optical element arrangement region, and the optical element is arranged at the opening.

16. The display substrate according to claim 2, wherein the orthographic projection of the active layer of each thin film transistor onto the base substrate falls within an orthographic projection of the light-shielding pattern of the light-shielding layer onto the base substrate, and the orthographic projection of the active layer of each thin film transistor onto the base substrate is non-overlapped with an orthographic projection of the imaging pattern of the light-shielding layer onto the base substrate.

17. The display substrate according to claim 2, wherein the orthographic projection of the light-shielding layer onto the base substrate only overlaps with the orthographic projection of the active layer of each thin film transistor onto the base substrate.

18. The display device according to claim 14, further comprising a light-shielding layer between the thin film transistor array and the base substrate, wherein an orthographic projection of an active layer of each thin film transistor onto the base substrate falls within an orthographic projection of the light-shielding layer onto the base substrate, and the light-shielding layer comprises a light-shielding pattern and an imaging pattern.

19. The display device according to claim 18, wherein the optical element arrangement region comprises a first region, the imaging pattern corresponds to the first region and is provided with a plurality of imaging holes arranged in an array, the optical element comprises a fingerprint recognition structure, and the fingerprint recognition structure is arranged corresponding to the first region.

20. The display device according to claim 18, wherein the optical element arrangement region comprises a second region, the orthographic projection of the light-shielding pattern onto the base substrate is non-overlapped with an orthographic projection of the second region onto the base substrate, the optical element comprises at least one of a face recognition circuit, a distance detection circuit and an environment light detection circuit, and the at least one of the face recognition circuit, the distance detection circuit and the environment tight detection circuit is arranged corresponding to the second region.
